(19) United States
(12) Patent Application Publication
(10) Pub. No.: US 2019/0009362 A1
(43) Pub. Date: Jan. 10, 2019

(54) METHOD FOR PRODUCING A METAL-CERAMIC SUBSTRATE WITH PICOLASER

(71) Applicant: Heraeus Deutschland GmbH & Co. KG, Hanau (DE)

(72) Inventors: Richard WACKER, Stegaurach (DE); Alexander ROGG, Trabitz (DE)

(73) Assignee: Heraeus Deutschland GmbH & Co. KG, Hanau (DE)

(21) Appl. No.: 16/064,641

(22) PCT Filed: Dec. 21, 2016
(86) PCT No.: PCT/EP2016/082180

§ 371 Date: Jun. 21, 2018

(30) Foreign Application Priority Data
Dec. 22, 2015 (EP) 15201873.5

(51) Int. Cl. B23K 26/06; B23K 26/364; B23K 26/40; C04B 37/02; H01L 21/48; C03B 33/02

(52) U.S. Cl. CPC B23K 26/0626; B23K 26/364; B23K 26/40; C04B 2237/704; H01L 21/4807; C03B 33/0222; C04B 2237/366; C04B 37/026

(57) ABSTRACT

One aspect relates to a method of processing metallized ceramic substrates and to a metal-ceramic substrate obtained by this method.

The present invention relates to a method for processing metallized ceramic substrates and a metal-ceramic substrate, which is obtained by this method.

Metal-ceramic substrates which are obtained, for example, by the DCB, AMB and DAB processes, are known to the person skilled in the art. These metal-ceramic substrates are usually produced in the so-called “multiple-use”. In this multiple-use, the ceramic substrates exhibit on at least one surface side, but preferably on both surface sides of the ceramic layer, individual metallizations among which predetermined breaking lines run the ceramic layer, so that breaking through these predetermined breaking lines the large-area metal-ceramic substrate can be separated in single substrates, which can then form each the circuit board of a circuit or module.

A partial step of the manufacturing process of such metal-ceramic substrates in the multi-use is the separation of the single parts from the multiple-use, which is usually done by means of laser. In this case, CO₂ resonators with, for example, 250 to 400 watts are usually used. Due to the laser blind holes arranged close to each other are generated. These blind holes form a predetermined breaking line (perforation).

The locomotor system used in this step is usually equipped with an x-y desk for the metal-ceramic substrate and a rigid laser, since a CO₂ laser with a wavelength of about 10.6 μm is not fiber light conductive and by moving of the optics, the length of the optical path and thus the beam quality changes.

A lens is used to focus the laser. In turn, to protect them, a process gas is used (for example, compressed air or oxygen) that emerges from a process gas nozzle together with the laser light. In this way it is prevented that ejected from the substrate, partially molten material, contaminates the lens (the process gas prevents the ingress of contaminants in the nozzle). At the same time, however, the process gas also serves to blow molten material out of the laser cone.

Due to the frequently existing different demands on the scoring (on the one hand, the generation of a predetermined breaking line is required and on the other hand, a cutting or drilling, i.e. a cutting of the substrate is required) the corresponding devices for processing the metal-ceramic substrates are often with two different process nozzles equipped.

A disadvantage of the known methods is that the processing of populated substrates, such as chips and wire bonds, is made more difficult because the laser nozzle does not reach sufficiently close the substrate surface. As a result, can the laser cones not be sufficiently blown out and glass phases remain in the laser cones.

A disadvantage of the known methods is that laser dusts and splashes must be removed from the surface by a cleaning step.

A disadvantage of the known method is further that when cutting ceramics burrs arise that must be removed mechanically. This results in an increased process complexity and the risk of increased product scrap.

The commonly used CO₂ resonators also do not allow the processing of copper, so that copper cannot be cut through.

Another disadvantage of the CO₂ resonators used is that the penetration point (initial hole) of the ceramic is clearly visible. There occur more disturbing melting phases and residues. Due to the poor appearance, this initial hole usually has to be placed in the area of the failure part, which also means an increased effort for program creation and entails longer process times.

Furthermore, there is a need for a method by which metal-ceramic substrates can be laser-etched from the backside. Due to the manufacturing process, this is the concave side of the metal-ceramic substrate. Thereby the corners and edges of the substrate are upwards at some material combinations. Although the deflection of the metal-substrate ceramic can be reduced, it is not possible, however, with the usual CO₂ lasers to produce a sufficient depth of focus. Therefore, often in the edge area faulty laser-processing and scrap occur.

Based on this prior art, the present invention has the task of preferably avoiding the disadvantages of the prior art described above.

In particular, the present invention has the task to provide a method for processing ceramics or metal-ceramic substrates, which can be carried out with high cost-efficiency and high process capacity per laser system. The process should be particularly suitable for ceramics of the type Al₂O₃, ZTA (zirconium doped Al₂O₃), AlN and Si₃N₄. The process should preferably be carried out without the formation of residues on the substrates, i.e. laser dusts or cutting burrs.

Furthermore, the method according to the invention should preferably allow introduction of a predetermined breaking line or laser scribing line that breaks as accurately as possible, which requires the introduction of a sufficient laser depth and the introduction of a sufficient notch effect generating micro-cracks. In addition, the laser scribing lines should preferably not metallize in the subsequent galvanic processes.

The method according to the invention should furthermore preferably enable ablation and cutting through of copper of the metal-ceramic substrate.

Finally, the method according to the invention should preferably make it possible to process ceramic substrates which are equipped, for example, with chips and wire bonds, without having to accept the disadvantages which occur when the laser cone is not blown out.

These tasks are solved by a method for processing a metal-ceramic substrate, in which

a. a laser scribing line is generated as a predetermined breaking line in the metal-ceramic substrate using a laser beam; and/or

b. the metal-ceramic substrate is at least partially cut through using a laser beam.

The method according to the invention is then characterized in that the processing is carried out using a laser and when generating the laser scribing line as a predetermined breaking line or when cutting through, a pulse duration of the laser is used which is chosen such that essentially no melting phases of the ceramic material are formed.

Independently of this, the method according to the invention is also generally characterized in that when generating the laser scribing line as a predetermined breaking line or when the metal-ceramic substrate is cut through, process conditions of the laser are selected such that essentially no melting phases of the ceramic material are formed.

Glass phases are residues in the laser scribing line which are heated and fused by the laser, but which are not removed from the scribing line and solidify in the laser scribing line.

In the context of the present invention, the term “essentially no melting phases of the ceramic material” is understood if the laser scribing line contains preferably less than 30% by volume, more preferably less than 20% by volume, even more preferably less than 15% by volume and preferably more than 0.1% by volume, more preferably more than 0.5% by volume, more preferably more than 1.0% by volume, of the melting phase.

This amount of melting phase forms on the surface (superficial coverage). This melting phase is characterized by having micro-cracks which cause preferred notch effects and stress increases for the subsequent breaking of the ceramic.

In the context of the present invention, it is preferred if the laser scribing lines contain small amounts of melting phases, i.e. in particular the minimum quantities of melting phases described above.

The formation of too large amounts of melting phases of the ceramic material can be avoided if the laser is operated under certain process conditions. These include in particular

(a) the pulse duration of the laser;

(b) the penetration depth of the laser into the metal-ceramic substrate; and

(c) the power of the laser.

Hereinafter, preferred embodiments of the laser are described with which a formation of melting phases during processing of the ceramic can be essentially prevented.

In the method according to the invention, during the generation of the laser scribing line as a predetermined breaking line, it is possible for the laser scribing line to be generated in one crossing or in several crossings of the laser (embodiment a). Also, cutting through of the metal-ceramic substrate can be achieved in several crossings of the laser (embodiment b.).

In the context of the present invention, the laser may be selected from an n-sec laser, p-sec laser or f-sec laser, although according to the invention the use of a p-sec laser is preferred.

Furthermore, it is further preferred if the p-sec laser has a pulse duration, i.e. a duration of the laser pulse of preferably 0.1 to 100 ps, more preferably 0.5 to 50 ps, still more preferably 1 to 30 ps. With the selected pulse duration, it is possible to guide the laser process so that essentially no melting phases arise and thus essentially no laser splashes and laser dusts, which are deposited on the substrate surface, are formed. At the same time a sufficient notch effect in the laser scribing line is achieved with this pulse duration. Since, in the context of the present invention, essentially only cold dusts and no melting phases are formed, and because of a sufficiently large selected distance from the beam source to the substrate surface, the use of a process gas is possible, but not absolutely necessary.

The pulse energy, i.e. the energy content of a single laser pulse is preferably 10 to 500 μJ, more preferably 50 to 400 ρJ, even more preferably 100 to 350 μJ.

The p-sec laser preferably has a power of 20 to 400 W, more preferably 40 to 200 W, even more preferably 50 to 180 W, still more preferably 60 to 160 watts, still more preferably 80 to 130 watts, still more preferably 90 to 120 watts.

The processing speed of the laser is preferably at least 0.05 m/sec, more preferably at least 0.1 m/sec, more preferably at least 0.15 m/sec, even more preferably at least 0.20 m/sec, more preferably at least 0.25 m/sec.

The processing speed of the laser is preferably at most 20.0 m/sec, more preferably at most 19.0 m/sec, further preferably at most 18.0 m/sec, further preferably at most 17.0 m/sec, further preferably at most 16.0 m/sec.

The processing speed of the laser is preferably 0.05 to 20.0 m/sec, more preferably 0.1 to 19.0 m/sec, more preferably 0.15 to 18.0 m/sec, further preferably 0.20 to 17.0 m/sec, more preferably 0.25 to 16.0 m/sec.

The processing speed corresponds to the real speed with which the laser moves over the ceramic. Corresponding analogous results can be obtained if effective speeds of the laser are selected in which the above-defined real speeds according to the invention are divided by the number of crossings of the laser, whereby crossings from 2 to 50, preferably 2 to 40, more preferably 2 to 30, further preferably 2 to 20, can be assumed.

Surprisingly, it has also been found that there is a relation between the resonator power (x in watts) used by the laser and the maximum real processing speed (y in m/sec) of the laser.

The relation generally follows the formula below:

y=\sqrt{2,3·x−40}

Here, the maximum processing speeds are independent of the thickness of the ceramic.

If the real processing speeds are greater than generally stated above or calculated by the above formula, effective and safe breaking of the ceramic substrates along the laser scribing line is not possible.

In a further preferred embodiment, the processing speed of the laser is preferably at least 0.05 m/sec up to a maximum processing speed in m/sec, which is defined by the above-mentioned formula

y=\sqrt{2,3·x−40}

where x corresponds to the resonator power of the laser in W.

In a further preferred embodiment, the processing speed of the laser is preferably at least 0.1 m/sec up to a maximum processing speed in m/sec, which is defined by the above-mentioned formula

y=\sqrt{2,3·x−40}

where x corresponds to the resonator power of the laser in W.

In a further preferred embodiment, the processing speed of the laser is preferably at least 0.15 m/sec up to a maximum processing speed in m/sec, which is defined by the above-mentioned formula

y=\sqrt{2,3·x−40}

where x corresponds to the resonator power of the laser in W.

In a further preferred embodiment, the processing speed of the laser is preferably at least 0.20 m/sec up to a maximum processing speed in m/sec, which is defined by the above-mentioned formula

y=\sqrt{2,3·x−40}

where x corresponds to the resonator power of the laser in W.

In a further preferred embodiment, the processing speed of the laser is preferably at least 0.25 m/sec up to a maximum processing speed in m/sec, which is defined by the above-mentioned formula

y=\sqrt{2,3·x−40}

where x corresponds to the resonator power of the laser in W.

The spot diameter of the laser is preferably 20 to 80 μm, more preferably 30 to 70 μm, still more preferably 40 to 60 μm.

In a preferred embodiment of the present invention, the laser used is an IR laser.

The underlying tasks of the present invention are in particular solved by the use of an IR laser, more preferably a p-sec IR laser, wherein, without being bound by theory, it is assumed that the light of the p-sec IR beam is particularly effective coupled into the surface of the ceramic substrate or in the surface of the metal coating, i.e. it is absorbed by the ceramic substrate or the metal coating particularly effective. In addition, an IR laser has high energy efficiency, which is also advantageous for solving the above tasks.

A further advantage of using an IR laser for processing ceramic substrates or metal-ceramic substrates is that the IR laser light can be generated directly from diode light, whereas green laser light is generated at first from IR laser light with an efficiency of 60% and UV laser light in turn must be generated of green laser light with a further efficiency of also 60%.

The p-sec IR laser in contrast to, for example, a CO₂ laser, can be arranged significantly further away from the metal-ceramic substrate to be structured, as a result of which a higher depth of focus can be realized.

In addition, by means of an IR laser, a sufficiently high depth of focus can be achieved compared to a CO₂ laser.

When an IR laser is used in the present invention, the frequency of the IR laser is preferably 350 to 650 kHz, more preferably 375 to 625 kHz, still more preferably 400 to 600 kHz.

When an IR laser is used in the present invention, the pulse energy of the IR laser is preferably 100 to 300 μJ, more preferably 125 to 275 μJ, still more preferably 150 to 250 μJ.

The inventive method according to the alternatives a. and b. can be carried out in the presence of a process gas. The process gas is, for example, oxygen.

The inventive method according to the alternatives a. and b. is preferably performed in a device having a suction device that absorbs dusts caused by the laser processing.

The embodiments of the processing of ceramic substrates or metal-ceramic substrates are described in more detail below.

### Embodiment a.: Laser Scribing Line as a Predetermined Breaking Line in the Metal-Ceramic Substrate

The method according to the invention is suitable in a first embodiment for generating a laser scribing line as a predetermined breaking line in a metal-ceramic substrate.

The laser scribing line to be generated as a predetermined breaking line in the metal-ceramic substrate can be generated either continuously or discontinuously in the metal-ceramic substrate. In order that subsequent breakage of the metal-ceramic substrate is easily possible, it is preferable if the depth of the laser scribing line is 5 to 50%, more preferably 8 to 45%, still more preferably 10 to 40% of the layer thickness of the ceramic substrate.

In a conventional ceramic substrate, when the laser scribing line is generated as a predetermined breaking line, the laser parameters used, i.e. for example, pulse duration, frequency and power, are such that a depth of the scribing line of at least 20 μm, more preferably at least 30 μm, even more preferably at least 50 μm, each perpendicular to a planar surface of the ceramic substrate, is generated.

Due to the method according to the invention, scribing lines can be made, which exhibit deviant from these depths if necessary. For example, the inventive method can be designed so that the scribing depth is higher in the initial region of the scribing line, to facilitate initiation of the break or to optimize the fracture pattern in the transition between cutting and scribing contour. For example, in the case in which the outer contour of a metal-ceramic substrate is to be rounded and therefore must be cut due to the small radius of curvature, a hole may result at the corners of the metal-ceramic substrate, in which the fracture pattern from the scribing line will be stopped and re-initiated on the other side of the hole. In the area of reintroducing the crack into the laser scribing line, a higher scribing depth may then preferably be created to facilitate this process of crack reintroduction.

The scribing line to be generated according to the invention has a width of preferably 20 to 70 μm, more preferably 25 to 65 μm, even more preferably 30 to 60 μm, and preferably runs straight in the x/y direction of the metal-ceramic substrate. Therefore, according to the invention, the formation of arches or radii in the laser scribing line is preferably not provided. Preferably, for purposes of marking, contours are introduced by the laser in the metal-ceramic substrate.

As already stated, during the generation of the laser scribing line as a predetermined breaking line, preferably a pulse duration of the laser is used, which is selected so that essentially no melting phases of the ceramic material are formed during lasering.

Thus, the scribing line has essentially no glazings (so-called laser throw up) on the sides of the scribing line. Within the scribing line itself, there are preferably essentially no, or but at least, hardly residues of glass phases (i.e., material melted by the laser but not removed). Furthermore, in the method according to the invention, essentially no (at least hardly) laser dusts are deposited on the side of the laser scribing line.

The laser scribing line obtained according to the invention preferably has micro-cracks which arise due to thermal stresses during the lasering and are advantageous for the subsequent breaking of the scribing lines. In addition, the laser scribing line preferably does not metallize in the subsequent galvanic process steps.

In the context of the present invention, it is possible that the laser scribing line is generated by one crossing of the laser over the metal-ceramic substrate. In an alternative approach, the laser scribing line is created as a predetermined breaking line by several crossings of the laser, which may be preferable in order to reduce the specific energy input, i.e. energy per time. However, the number of crossings depends on the material, i.e. the metal coating or the ceramic used and on the desired processing depth.

The processing speed of the laser depends on the actual process conditions, i.e. the laser used and the materials used for metal coating and ceramic as well as the desired processing depth.

The processing speed of the laser is preferably as stated above.

Another advantage associated with the use of an IR laser is the avoidance of crossing points between two scribing lines. When two laser scribing lines cross over, using a CO₂ laser it is possible that the two laser pulses overlap at the same location. This increases the depth of the bullet hole. In extreme cases, it can come to a bullet, which extends to the opposite ceramic side. This can have a negative effect on the breaking behavior or on the subsequent mechanical strength of the substrate. Due to the very high precision of the IR laser technology, especially when using a p-sec-IR laser, as well as the fact that all scribing lines are crossed multiple times and thus no favorite scribing line is resulting, one of the scribing lines can simply be interrupted or the parameters in the intersection area are adjusted and thus an increased scribing depth in the crossing area is avoided.

Another advantage over the use of CO₂ lasers results in the pre-lasering of ceramics with the IR laser provided according to the invention, in particular p-sec IR laser. In the field of metal-ceramic substrates, there are products that use pre-lasered ceramics. Here, the ceramic is already lasered before the bonding process of metal and ceramic. Examples include products with via (vias) or protruding metal (lead-off). In the case of processing with CO₂ lasers, the dusts and laser throw up, arising during the lasering, must be removed again. This is done for example with disc brushes, ultrasonic cleaning systems, lapping or other mechanical methods. Chemical processes are not useful in the case of alumina due to its high chemical resistance. By using appropriate IR laser no dusts and throw ups result, which must be removed. An appropriate purification can therefore be avoided.

### Embodiment b.: Cutting the Metal-Ceramic Substrate Using a Laser Beam

Partly there is a need to introduce contours in the metal-ceramic substrates, which differ from a straight line. These may be, for example, holes in the center of a metal-ceramic substrate or roundings at the corners of the metal-ceramic substrate. Such contours can be obtained by cutting the ceramic of the metal-ceramic substrate using the laser.

If, in the context of the present invention, the ceramic substrate is cut through by means of a laser, there is no penetration point at which an initial severing of the ceramic took place. Therefore, it is not necessary in the context of the present invention to stab outside the contour and to approach the actual cutting contour with a starting ramp.

If, in the context of the present invention, the ceramic substrate is severed using the laser, the cutting edges have an angle, which usually deviates from a right angle by preferably at most 30°, more preferably at most 25^{°} This results in a hole that is larger on the top than on the bottom.

A further advantage of the inventive separation of the ceramic substrate with an IR laser, in particular p-sec-IR laser, is that at the bottom, i.e. the laser exit side, no burrs formed by melting phase are resulting, which would have to be removed in an additional procedural step.

### Advantages of the Embodiments a. and b.

Considering the above-described embodiments a. and b., it is possible to process the metal coating and the ceramic substrate with the same laser. As a result, a production of metal-ceramic substrates with structured metal coating can be realized cost-effectively. In detail it is possible,

I) to ablate only partially the upper metal coating or cut through to the ceramic and, for example, to produce fine structures in the metal coating, which are not possible with an etching process;

II) to cut through the metal coating and the ceramic substrate to the lower metal coating (Thus, the basis for via-hole can be created. When filling appropriate blind holes with a conductive material, a through hole is made. Filling material are, for example, metallic pastes or galvanically generated materials.);

III) to cut through the metal coating and ceramic substrate or to cut only the metal coating or the ceramic substrate, if there is no metal coating on top of the ceramic substrate (for example, because it has already been etched away or not even applied).

The inventive method of processing a metal-ceramic substrate according to embodiment a. and b. is preferably carried out in the presence of a process gas, wherein for example oxygen or compressed air can be used as the process gas. As stated above, the use of a process gas is not mandatory, but may be advisable to protect the beam source from contamination. In this case, the use of compressed air would be the preferred alternative.

Since in the method according to the invention, dusts are produced by the laser processing, it is particularly preferred if the device used has a suction device that absorbs dusts which are produced by the laser processing.

The suction device can be formed, for example, by a suctioning tube or a suction box surrounding the projected laser light and whose lower edge is at a distance from the surface of the metal-ceramic substrate of preferably 0.5 to 10 cm, more preferably 0.75 to 7.5 cm, more preferably 1 to 5 cm.

Another object of the present invention is a metal-ceramic substrate, which is obtained by the method described above.

The metal-ceramic substrate according to the invention may have a continuous or interrupted scribing trench having, for example, a depth of at least 20 μm, more preferably at least 30 μm, even more preferably at least 50 μm, each perpendicular to a planar surface of the ceramic substrate.

For a ceramic substrate having a layer thickness of 0.38 mm, the target depth of the laser scribing line is preferably 30 to 120 μm, more preferably 40 to 110 μm, even more preferably 50 to 100 μm.

For a ceramic substrate having a layer thickness of 0.63 mm, the target depth of the laser scribing line is preferably 40 to 140 μm, more preferably 50 to 130 μm, still more preferably 60 to 120 μm.

In addition, the metal-ceramic substrate has a width of the scribing trench of preferably 15 to 75 μm, more preferably 20 to 70 μm, still more preferably 25 to 65 μm.

The ceramic substrate processed by the method according to the invention is essentially free of glazings on the sides of the scribing line and within the scribing line essentially free of residues of glass phases. Due to the micro-cracks formed in the region of the scribing line, breaking of the ceramic substrate is possible without difficulty.

The metal-ceramic substrate of the present invention may have a contour obtained by the treatment with the IR laser, which deviates from a straight line and which has been formed by cutting the ceramic substrate using a laser beam. Moreover, it is possible that the metal-ceramic substrate according to the invention exhibits holes and/or roundings at the corners, which have been produced due to cutting through the ceramic substrate.

The metal-ceramic substrate obtained by the IR laser method with a p-sec IR laser, has cutting edges at an angle which deviates from a right angle by preferably at most 30°, more preferably at most 25°. If holes are introduced into the metal-ceramic substrate by the IR laser method, their size may be different on the two sides of the ceramic substrate. However, preferably, the metal-ceramic substrate exhibits at the hole and/or at the rounding, no burr.

Due to the IR laser method according to the invention, metal-ceramic substrates are obtainable which have a coding on the metal coating of the ceramic substrate. This coding is preferably effected by ablation of the metal coating by the IR laser.

With the method according to the invention, moreover, metal-ceramic substrates are obtainable in which the metallization on the ceramic substrate has at least one edge attenuation or in which the metallization has at least one recess for receiving electronic components, in particular chips, wherein the recess was generated by a laser treatment. The present invention is explained in more detail with reference to the following examples:

### EXAMPLE 1

### (1) Metal-Ceramic Substrate:

The following tests are performed on a metal-ceramic substrate obtained by the DCB method.

The ceramic substrate is an Al₂O₃ ceramic material. The layer thickness of the ceramic substrate is 0.38 mm (test series 1) and 0.63 mm (test series 2).

### (2) Laser

The subsequent tests are carried out with the following laser:

Power: 100 W

Laser source: IR

Pulse duration laser: 0.1 to 100 ps

Pulse energy laser: 10 to 500 μJ

Spot diameter: 30 μm

Frequency laser: 350 to 650 kHz

With the laser described above, a laser scribing line is generated in the ceramic substrate, and then the ceramic substrate is broken in the laser scribing line.

### (3) Results

| | | Breaking behavior |
|---|---|---|
| Test series | real processing speed | ceramic substrate |
| 1 | 7.5 m/sec | + |
| 1 | 10 m/sec | + |
| 1 | 15 m/sec | 0 |
| 1 | 20 m/sec | − |
| 2 | 7.5 m/sec | + |
| 2 | 10 m/sec | + |
| 2 | 15 m/sec | 0 |
| 2 | 20 m/sec | − |

### Rating:

+: good breaking behavior

0: average breaking behavior

−: bad breaking behavior

The test series show that real speeds of the IR laser between up to 15 m/sec are suitable for breaking behavior. Higher real speeds of the IR laser lead to a poor breaking behavior.

With these speeds of the IR laser, glass phases in the laser scribing line are essentially avoided and sufficient micro-cracks are formed so that it is possible to cut through the ceramic.

Real speeds below 0.05 m/sec are disadvantageous because too deep scribing lines (too much formation of glass phases) result. In addition, real speeds below 0.05 m/sec are disadvantaged for economic reasons.

1-15. (canceled)

16. A method for processing of metal-ceramic substrates, comprising:
generating a laser scribing line as a predetermined breaking line in the metal-ceramic substrate using a laser beam; or
at least partially cutting through the metal-ceramic substrate using a laser beam;
wherein the processing is carried out using a laser and when generating the laser scribing line as a predetermined breaking line or when cutting through, a pulse duration of the laser is used which is chosen such that essentially no melting phases of the ceramic material are formed.

17. The method according to claim 16, wherein the laser scribing line is formed continuously or discontinuously.

18. The method according to claim 16, wherein the laser is a p-sec laser.

19. The method according to claim 16, wherein the laser has a pulse duration of 0.1 to 100 ps.

20. The method according to claim 16, wherein, during the generation of the laser scribing line as a predetermined breaking line, the laser scribing line is generated in several crossings of the laser and/or the at least partially cutting through of the metal-ceramic substrate occurs in several crossings of the laser.

21. The method according to claim 16, wherein the laser is an IR laser.

22. The method according to claim 21, wherein the IR laser has a power of 60 to 160 watts.

23. The method according to claim 21, wherein the frequency of the IR laser is 350 to 650 kHz.

24. The method according to any claim 21, wherein the pulse energy of the IR laser is 100 to 300 μJ.

25. The method according to claim 21, wherein the spot diameter of the IR laser is 20 to 100 μm.

26. The method according to claim 16, wherein the method is carried out in a device having a suction device that absorbs dusts, which result from the laser processing.

27. A metallized ceramic substrate obtained by the method according to claim 16.

28. The metallized ceramic substrate according to claim 27, wherein the ceramic substrate has a continuous scribing trench.

29. The metallized ceramic substrate according to claim 27, wherein the ceramic substrate has a continuous scribing trench with a depth of at least 20 μm, each perpendicular to a planar surface of the ceramic substrate.

30. The metallized ceramic substrate according to claim 27, wherein the ceramic substrate has a contour which deviates from a straight line and which has been produced by cutting the ceramic substrate using a laser beam.
